(19) United States
(12) Patent Application Publication
(10) Pub. No.: US 2013/0264536 A1
(43) Pub. Date: Oct. 10, 2013

(54) SIOX-BASED NONVOLATILE MEMORY ARCHITECTURE

(71) Applicants: James M. Tour, Bellaire, TX (US); Jun Yao, Sugarland, TX (US); Burt Fowler, Buda, TX (US); Glenn Mortland, Austin, TX (US)

(72) Inventors: James M. Tour, Bellaire, TX (US); Jun Yao, Sugarland, TX (US); Burt Fowler, Buda, TX (US); Glenn Mortland, Austin, TX (US)

(73) Assignees: Privatran, Inc., Austin, TX (US); William Marsh Rice University, Houston, TX (US)

(21) Appl. No.: 13/821,632

(22) PCT Filed: Sep. 8, 2011
(86) PCT No.: PCT/US11/50812

§ 371 Date: Jun. 14, 2013

Related U.S. Application Data
(60) Provisional application No. 61/380,842, filed on Sep. 8, 2010.

(51) Int. Cl. H01L 27/24; H01L 45/00

(52) U.S. Cl. CPC H01L 27/2409; H01L 27/2436; H01L 45/16
USPC 257/5; 257/2; 438/104

(57) ABSTRACT

Various embodiments of the present invention pertain to memresistor cells that comprise: (1) a substrate; (2) an electrical switch associated with the substrate; (3) an insulating layer; and (3) a resistive memory material. The resistive memory material is selected from the group consisting of SiOₓ, SiOₓH, SiOₓN_{y}, SiOₓN_{y}H, SiOₓCz, SiOₓC_{z}H, and combinations thereof, wherein each of x, y and z are equal or greater than 1 or equal or less than 2. Additional embodiments of the present invention pertain to memresistor arrays that comprise: (1) a plurality of bit lines; (2) a plurality of word lines orthogonal to the bit lines; and (3) a plurality of said memresistor cells positioned between the word lines and the bit lines. Further embodiments of the present invention provide methods of making said memresistor cells and arrays.

### CROSS-REFERENCE TO RELATED APPLICATIONS

This application claims priority to U.S. Provisional Patent Application No. 61/380,842, filed on Sep. 8, 2010, the entirety of which is incorporated herein by reference.

### STATEMENT REGARDING FEDERALLY SPONSORED RESEARCH

This invention was made with government support under Grant No. NNX11CH49P, awarded by the National Aeronautics and Space Administration; Grant No. W911NF-08-C-0019, awarded by the U.S. Department of Defense; Grant No. W911NF-08-C-0133, awarded by the U.S. Department of Defense; Grant No. FA9550-10-C-0098, awarded by the U.S. Department of Defense; and Grant No. N00039-10-0056, awarded by the U.S. Department of Defense. The government has certain rights in the invention.

### BACKGROUND OF THE INVENTION

SiOₓ-based resistive switching has shown promising memory properties. A need exists to apply and utilize such resistive switching. However, proper device structural engineering and architecture are needed. The present invention addresses these needs.

### BRIEF SUMMARY OF THE INVENTION

In some embodiments, the present invention pertains to memresistor cells. In various embodiments, such memresistor cells generally comprise: (1) a substrate; (2) an electrical switch associated with the substrate; (3) one or more insulating layers; and (4) a resistive memory material. In some embodiments, the insulating layer is above the substrate and the electrical switch, and the resistive memory material is above the insulating layer. In some embodiments, the electrical switch may also be associated with two or more conductive elements. In some embodiments, the memresistor cell has two terminals.

In some embodiments, the resistive memory material comprises one or more SiOₓ-based compositions, such as SiOₓ, SiOₓH, SiOₓN_{y}, SiOₓN_{y}H, SiOₓC_{z}, SiOₓC_{z}H, and combinations thereof. In such embodiments, x, y and z may each be equal or greater than 1 or equal or less than 2.

In some embodiments, the resistive memory material may also comprise a compound containing at least three elements (i.e., an “MEA compound”), where “M” is selected from the group consisting of Si, C, Ge, In, Sn, Pb, Ti, Zr, Hf, Sr, Ba, Y, La, V, Nb, Ta, Cr, Mo, W, Fe, Ni, Cu, Ag, Zn, Al, and combinations thereof; “E” is selected from the group consisting of O, N, P, B, Sb, S, Se, Te, and combinations thereof and “A” is selected from the group consisting of H, Li, Na, K, F, Cl, Br, I and combinations thereof.

In some embodiments, the electrical switch may be a transistor, such as a field effect transistor (FET), an n-channel FET, a p-channel FET, a metal-oxide semiconductor FET (MOS FET), and a bipolar FET. In some embodiments, the electrical switch may be a diode, such as an n-p diode, a p-n diode, and a Schottky diode.

In further embodiments, the present invention provides memresistor arrays that comprise: (1) a plurality of bit lines; (2) a plurality of word lines that are orthogonal to the bit lines; and (3) a plurality of memresistor cells that are positioned between the bit lines and word lines. Additional embodiments of the present invention pertain to methods of making the memresistor cells and memresistor arrays of the present invention. As set forth in more detail below, the memresistors and memresistor arrays of the present invention have numerous applications in various fields and environments, including applications as flash memory drives in outer space.

### BRIEF DESCRIPTION OF THE FIGURES

FIG. 1 is a cross-section of a memresistor cell having a diode.

FIG. 2 is a cross-section of a memresistor cell having an FET.

FIG. 3 is a top-down view of a memresistor array containing memresistor cells with diodes.

FIG. 4 is a schematic of a memresistor array containing memresistor cells with diodes.

FIG. 5 is a schematic of an FET-based memresistor cell within a memresistor array.

FIG. 6 is an electroforming plot for various memresistor cells. The numbers indicate the voltage sweeping orders.

FIG. 7 is a program (erase, write and read) diagram and memory cycling plot for various memresistor cells.

FIG. 8 is a current-voltage plot showing initial leakage current of seven SiOₓ-based memresistor cells receiving forming gas anneal. The devices were tested in a vacuum probe chamber.

FIG. 9 is a current-voltage plot of a SiOₓ-based memresistor cell in a vacuum probe chamber showing switching performance.

FIG. 10 is a multiple current-voltage plot of hermetically-sealed SiOₓ-based memresistor cell with inset showing short-circuit calibration device response.

### DETAILED DESCRIPTION OF EXEMPLARY EMBODIMENTS

It is to be understood that both the foregoing general description and the following detailed description are exemplary and explanatory only, and are not restrictive of the invention, as claimed. In this application, the use of the singular includes the plural, the word “a” or “an” means “at least one”, and the use of “or” means “and/or”, unless specifically stated otherwise. Furthermore, the use of the term “including”, as well as other forms, such as “includes” and “included”, is not limiting. Also, terms such as “element” or “component” encompass both elements or components comprising one unit and elements or components that comprise more than one unit unless specifically stated otherwise.

The section headings used herein are for organizational purposes only and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature and similar materials defines a term in a manner that contradicts the definition of that term in this application, this application controls.

Various embodiments of the present invention provide resistance-change memory cells (i.e., memresistor cells) that can be utilized in memory devices. In various embodiments, such memresistor cells generally comprise: (1) a substrate; (2) an electrical switch associated with the substrate; (3) one or more insulating layers; and (4) a resistive memory material. In some embodiments, the resistive memory material is associated with two or more conductive elements, such as electrodes. In various embodiments, the electrical switch may be a transistor or a diode. In some embodiments, the electrical switch may also be associated with two or more conductive elements.

In further embodiments, the present invention provides memresistor arrays that comprise: (1) a plurality of bit lines; (2) a plurality of word lines that are orthogonal to the bit lines conductors; and (3) a plurality of memresistor cells positioned between the word lines and bit lines. Additional Embodiments of the present invention provide methods of forming memresistor memory cells, methods of forming memresistor arrays, and devices that incorporate such memresistor cells and arrays.

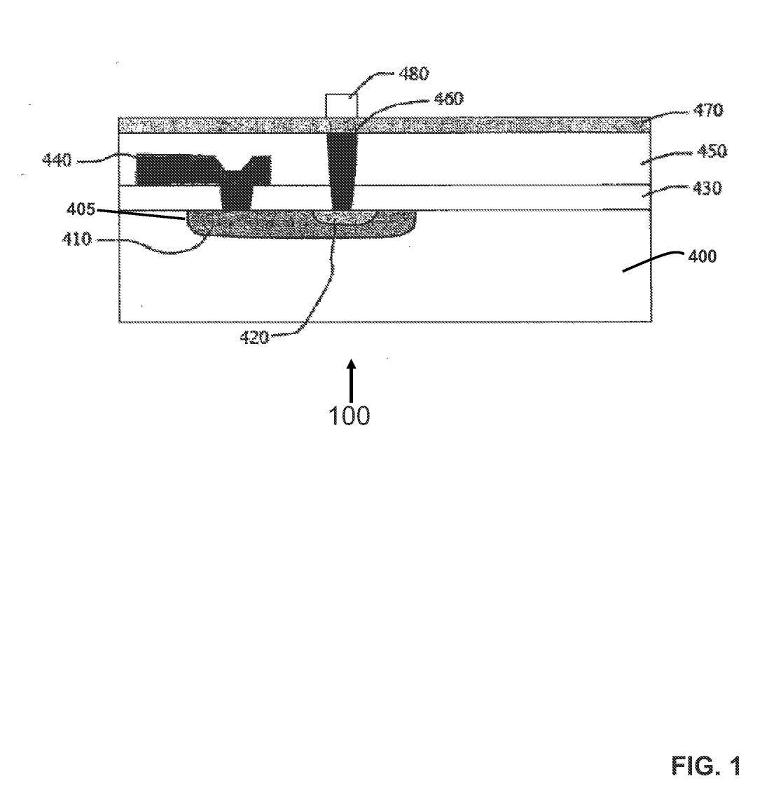

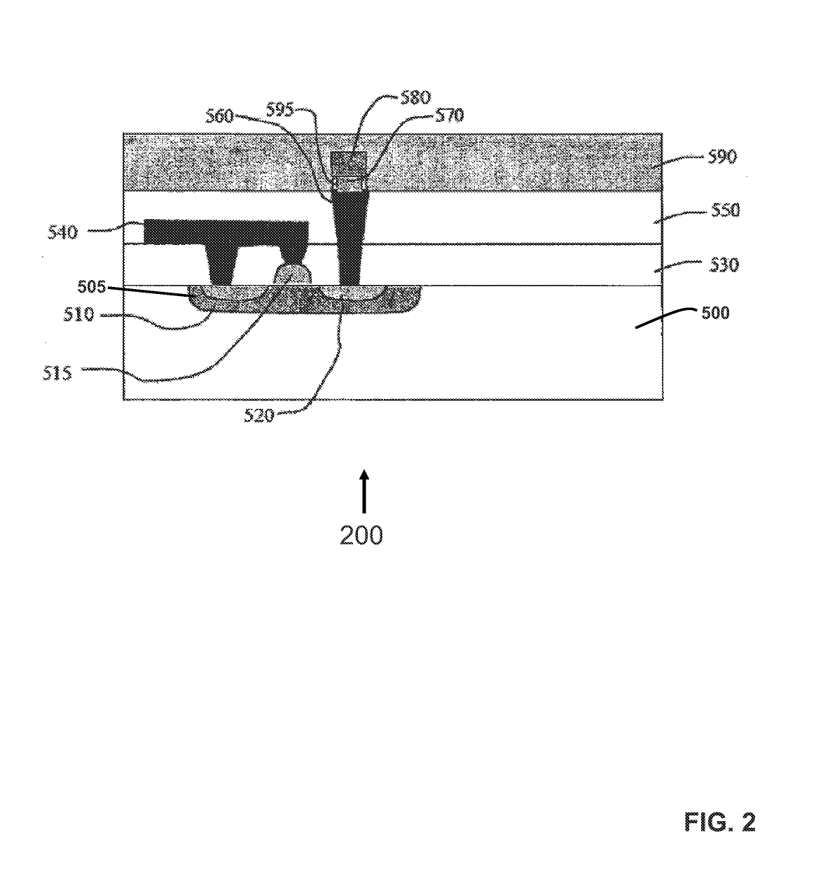

Non-limiting examples of memresistor cells are shown in FIGS. 1-2. For instance, FIG. 1 shows a cross-section drawing of a two-terminal memresistor cell 100 having a diode as the electrical switch. In this embodiment, memresistor cell 100 consists of substrate 400, diode 405 embedded in the substrate, insulating layers 430 and 450, and resistive memory material 470.

In this embodiment, diode 405 also contains a first doped area 410, and a second doped area 420. In addition, diode 405 is associated with conductive elements 440 and 460. In turn, conductive element 460 is associated with plug 480.

Likewise, FIG. 2 shows a cross-section drawing of a two-terminal memresistor cell 200 having an field effect transistor (FET) as the electrical switch. In this embodiment, memresistor cell 200 consists of substrate 500, FET 505 embedded in the substrate, insulating layers 530, 550 and 590, and resistive memory material 570.

In this embodiment, FET 505 also contains a first doped area 510, a second doped area 520, and an FET gate 515. In addition, FET 505 is associated with conductive elements 540 and 560. In turn, conductive element 560 is associated with conductive element 580 and opening 595. Insulating layer 590 provides electrical insulation for conductive element 580. The aforementioned memresistor cells will be described in more detail below.

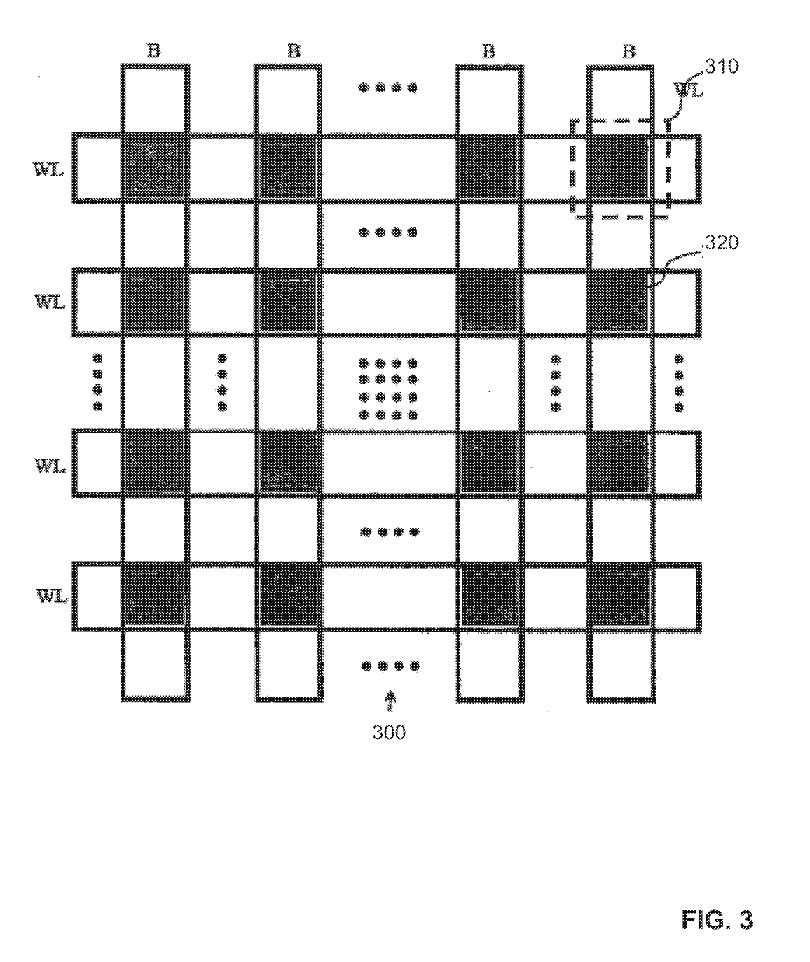

Examples of memresistor arrays containing memresistor cells are shown in FIGS. 3-5 and also described in more detailed below. For instance, FIG. 3 is a top down view representation of one embodiment of a memresistor array 300 having word lines (labeled as WL) orthogonal to bit lines (labeled as B). In this embodiment, memresistor array 300 contains areas 310 that house memresistor cells 320 between the word lines and bit lines.

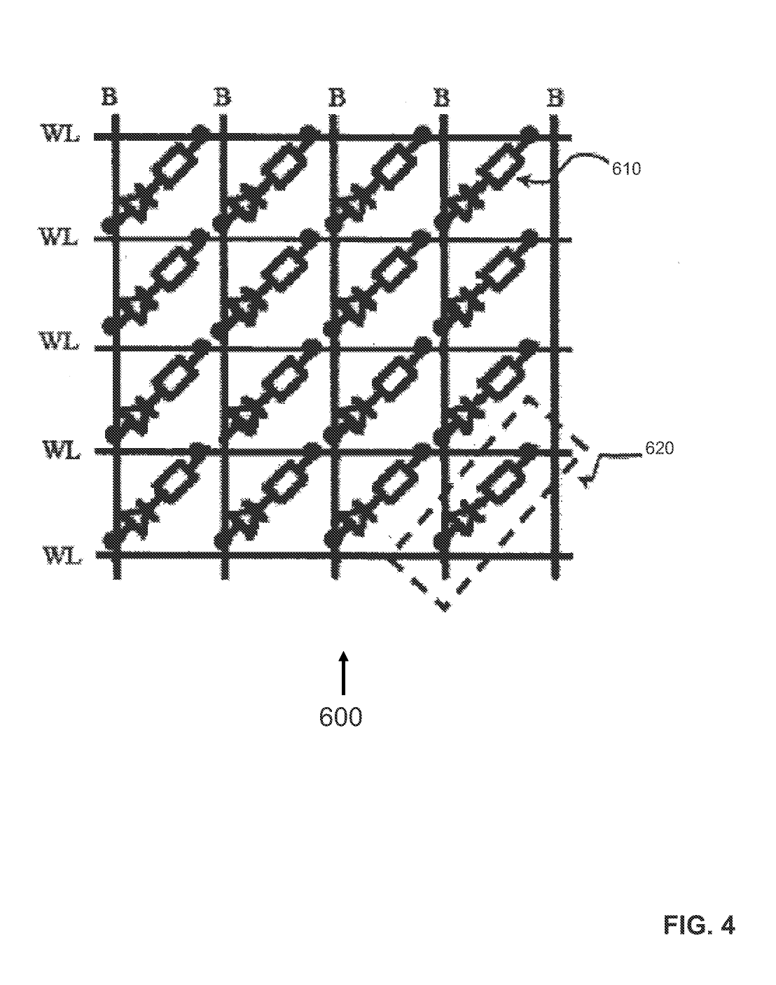

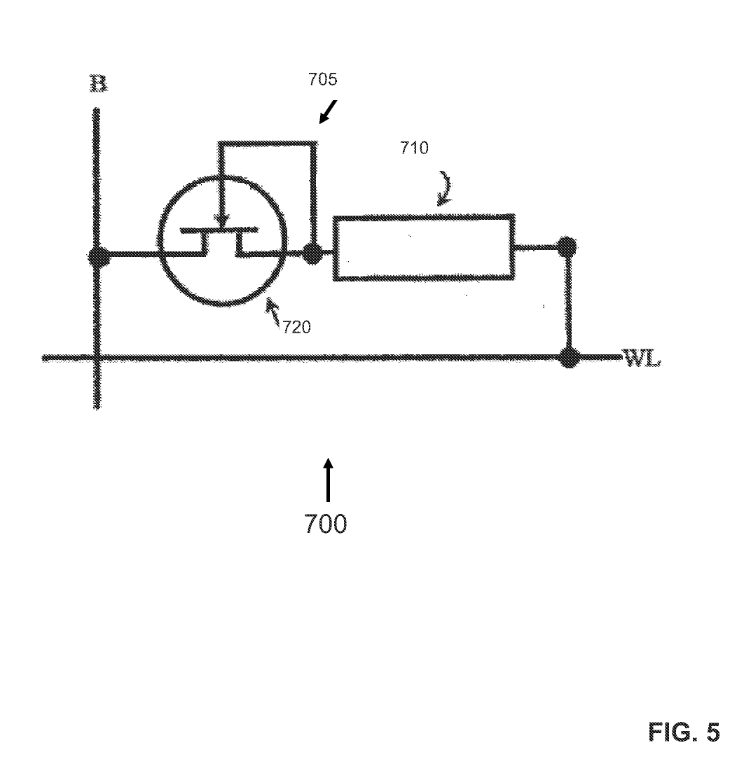

FIG. 4 is an illustration of another embodiment of a memresistor array. This embodiment shows memresistor array 600 with multiple diode-containing memresistor cells 610 that are embedded between word lines (WL) and bit lines (B) in areas 620. Another illustration of a memresistor array is shown in FIG. 5, where memresistor array 700 contains memresistor cell 705 between word lines (WL) and bit lines (B). In this embodiment, memresistor cell 705 contains an FET 720 that is connected to resistive memory material 710.

Additional details about the various embodiments of the present invention will now be described in more detail as specific and non-limiting examples.

Memresistor Cells

Memresistor cells of the present invention generally include: (1) a substrate; (2) an electrical switch associated with the substrate; (3) one or more insulating layers; and (4) a resistive memory material. In some embodiments, the resistive memory material is associated with two or more conductive elements, such as conductive electrodes. In some embodiments, the electrical switch may also be associated with two or more conductive elements. In some embodiments, the memresistor cell has two terminals.

The aforementioned components may be arranged in various manners. For instance, in some embodiments, the insulating layer is above the substrate and the electrical switch while the resistive memory material is above the insulating layer. See, e.g., FIGS. 1-2.

Additional arrangements can also be envisioned. For example, in some embodiments, the resistive memory material can be associated with a first conductive element formed in the substrate and a second conductive element overlying the resistive memory material, where the resistive memory material is adjacent to the electrical switch. In various arrangements, a top electrode associated with the memresistor cell can be patterned and etched in order to define active device regions where a vertical edge is etched into the memresistor cell. The top electrode can also be used as a hardmask to define the vertical edge. In various arrangements, the top electrode can also be covered by an insulating layer to provide electrical isolation between the top electrode and any additional conductive and insulator layers needed in the manufacturing process. Likewise, isotropic etching of the memresistor cell can be used to undercut the top electrode hardmask in order to form a cavity with controlled size when an insulating layer covers the top electrode.

Reference will now be made to various components of memresistor cells as non-limiting examples.

Substrate

Substrates in memresistor cells generally refer to compositions that can house or support electrical switches. In some embodiments, the substrate is a semiconducting substrate. In some embodiments, the substrate is an insulating substrate. In more specific embodiments, the substrate also contains a dielectric layer. In some embodiments, the substrate may also contain an oxide layer. Examples of substrate compositions include, without limitation, silicon, silicon dioxide, aluminum oxide, sapphire, germanium, gallium arsenide (GaAs), alloys of silicon and germanium, indium phosphide (InP), and combinations thereof. The substrates of the present invention may also have various shapes. For instance, in some embodiments, the substrates may be in the form of discs (e.g., wafers), cylinders, cubes, spheres, and the like.

Electrical Switches

Electrical switches generally refer to devices or components that can control or affect current flow. In some embodiments, an electrical switch associated with a memresistor cell is a diode. Examples of suitable diodes include, without limitation, semiconductor diodes, vacuum tube diodes, and thermionic diodes. More specific examples of diodes suitable for use as electrical switches in the present invention include, without limitation, n-p diodes, p-n diodes, and Schottky diodes.

In some embodiments, an electrical switch associated with a memresistor cell is a transistor. In some embodiments, the transistor is an FET. In more specific embodiments, the transistor is an n-channel FET, a p-channel FET, a metal oxide semiconductor (MOS)-based transistor, MOS-FET, and bipolar FET. In other embodiments, the transistor is an n-p-n or a p-n-p bipolar junction transistor (BJT).

In some embodiments, the electrical switches of the present invention have multiple doped areas. For instance, electrical switches of the present invention may have first and second doped areas that are of different doping types. For instance, in some embodiments, the first doped area may be a p-doped area while the second doped area may be an n-doped area.

Conductive Elements

In various embodiments, the electrical switches of the present invention may also be associated with two or more conductive elements. Such association may be direct or indirect.

Various conductive elements may be utilized. In some embodiments, the conductive elements may include polysilicon, n-doped polysilicon, p-doped polysilicon, doped single-crystal silicon, metal silicides, and various metals. Metals that can be utilized as conductive elements include, without limitation, tungsten, titanium, titanium nitride, titanium silicide, titanium tungsten, cobalt silicide, nickel silicide, tantalum, tantalum nitride, aluminum, gold, and copper.

As illustrated in FIGS. 1-2, the conductive elements of the present invention may have various shapes. For instance, in some embodiments, the conductive elements may be in the form of wires, rods, tubes, and other similar shapes. In some embodiments, the conductive elements may be bit lines and word lines, as illustrated in FIGS. 3-5 and discussed in more detail below.

Insulating Layers

Insulating layers generally refer to compositions that can prevent or mitigate heat loss. Insulating layers may also show high resistance to electrical conductivity. The memresistor cells of the present invention can be associated with one or more insulating layers. In some embodiments, memresistor cells have a single insulating layer. In some embodiments, memresistor cells have two insulating layers. In some embodiments, memresistor cells may have multiple insulating layers, such as 3-5 insulating layers.

Various insulating layers may be used with the memresistor cells of the present invention. In some embodiments, the insulating layer is composed of silicon dioxide (SiO₂). In some embodiments, the insulating layer is composed of Si₃N₄, SiCOH, Al₂O₃ or various polyimide materials. The use of other insulating layers not disclosed here can also be envisioned by persons of ordinary skill in the art.

Resistive Memory Materials

Resistive memory materials generally refer to compositions with electrical conductivity that can be reversibly modified by application of different bias voltages. In some embodiments, one programming bias voltage will drive the resistive memory material into a high-conductivity state, and another programming bias voltage will drive the resistive memory material into a low-conductivity state. The state of the resistive memory material can be determined by applying a third bias voltage and measuring the current flow through the resistive memory material, where the third bias voltage does not alter the programmed state. Resistive memory materials are further generally classified as being bipolar, which requires the programming voltage polarity to be different, or as being unipolar, where all programming and state measurement voltages are of a single polarity.

In some embodiments, resistive memory materials can act as a reversible memory. In some embodiments, the resistive memory material has one or more programmable resistance states. In some embodiments, the resistive memory material may also exhibit a reversible switching mechanism.

Various resistive memory materials may be used in the memresistor cells of the present invention. In some embodiments, the resistive memory materials include, without limitation, Si, O, H, C and N. In more specific embodiments, the resistive memory materials include, without limitation, SiOₓ, SiOₓH, SiOₓN_{y}, SiOₓN_{y}H, SiOₓC_{z}, SiOₓC_{z}H, and combinations thereof. In such embodiments, each of x, y and z may be equal or greater than 1 or equal or less than 2. In some embodiments, the x ratio of Oₓ to Si is greater than or equal to 0 and less than or equal to 2. In some embodiments, the y ratio of N_{y} to Si is in the range from 1.33 to 0. In some embodiments, the z ratio of C_{z} to Si is in the range from 1 to 0.

In some embodiments, the resistive memory material may also include a compound containing at least three elements (i.e., an “MEA” compound), where “M” is at least one of Si, C, Ge, In, Sn, Pb, Ti, Zr, Hf, Sr, Ba, Y, La, V, Nb, Ta, Cr, Mo, W, Fe, Ni, Cu, Ag, Zn, Al, and combinations thereof “E” is at least one of O, N, P, B, Sb, S, Se, Te, and combinations thereof and “A” is at least one of H, Li, Na, K, F, Cl, Br, I and combinations thereof. In more specific embodiments, the resistive memory material consists of SiO₂, such as amorphous SiO₂ or hydrogenated SiO₂. In some embodiments, the memresistor cell is hydrogenated SiO₂ that is exposed to thermal anneal in ambient containing at least one of H₂, H₂O and D₂.

In some embodiments, the resistive memory material has one or more programmable resistance states. In some embodiments, the resistive memory material has two programmable resistance states. In more specific embodiments, the current difference between the two programmable resistance states is at least greater than 1,000,000 to 1. In various other embodiments, the current difference between the two programmable resistance states is at least greater than 100,000 to 1, at least greater than 10,000 to 1, at least greater than 1000 to 1, at least greater than 100 to 1, or at least greater than 10 to 1.

In some embodiments, the resistive memory material may have three or more programmable resistance states. In some embodiments, the resistive memory material has three programmable resistance states that consist of a low current state (e.g., 10⁻¹² to 10⁻⁹ A), a medium current state (e.g., 10⁻⁹ to 10⁻⁶ A) and a high current state (e.g., 10⁻⁶ to 10⁻³ A).

The resistive memory materials of the present invention may also have various programmable properties. For instance, in some embodiments, the resistive memory materials may not be programmable by heat, X-ray, heavy ion irradiation, or heavy proton irradiation. In some embodiments, the resistive memory materials may retain their state when exposed to heat, X-ray, heavy ion irradiation, or heavy proton irradiation.

The resistive memory materials of the present invention may also have various heating properties. For instance, in some embodiments, the resistive memory materials may not be programmable by heating at temperatures of less than about 200° C. for periods of time ranging from less than 5 seconds to more than 30 minutes. In some embodiments, the resistive memory materials may not be programmable by heating at temperatures of less than about 300° C. for periods of time ranging from less than 5 seconds to more than 30 minutes. In some embodiments, the resistive memory materials may not be programmable by heating at temperatures of less than about 400° C. for periods of time ranging from less than 5 seconds to more than 30 minutes.

In some embodiments, the resistive memory materials of the present invention may be in the form of layers with various thicknesses. For instance, in some embodiments, the resistive memory materials may have thicknesses that range between about 10 nm to about 1000 nm. In some embodiments, the resistive memory materials may have thicknesses that range from about 1 μm to about 10 μm. The resistive memory materials of the present invention may also have various shapes, including square-like shapes, circular shapes, and rectangular shapes.

In some embodiments, the resistive memory materials of the present invention may also be associated with two or more conductive elements, such as electrodes and the conductive elements described previously. In more specific embodiments, the resistive memory materials of the present invention are associated with two electrodes.

Memresistor Arrays

Additional embodiments of the present invention pertain to memresistor arrays. Such arrays generally include a plurality of bit lines, a plurality of word lines orthogonal to the bit lines, and a plurality of memresistor cells (as previously described). The memresistor cells can be positioned between the word lines and bit lines in various arrangements. See, e.g., FIGS. 3-5.

For instance, in some embodiments, a substrate of a memresistor cell may be in contact with a bit line while the resistive memory material may be in contact with a word line. Likewise, in other embodiments, a substrate may be in contact with a word line while the resistive memory material may be in contact with a bit line. In further embodiments, the bit line and the word line may be in direct contact with the electrical switches of memresistor cells. In some embodiments, the bit lines and word lines may represent or define the conductive elements associated with the electrical switches in memresistor cells.

For instance, FIG. 3 is a top down view representation of one embodiment of memresistor array 300 with a plurality of word lines that are orthogonal to bit lines. Area 310 represents the area where memresistor cells 320 are between the word line and bit line conductors. In this embodiment, the upper conductive element and the lower conductive element of memresistor cells 320 are orthogonal. The lower conductive element is defined as the bit line and the upper conductive element is defined as the word line in this embodiment.

Although the bit lines and word lines are defined to have lower and upper positions, the actual positions of the bit lines and word lines can vary in different embodiments. In FIG. 3, the programmable resistive material layer has the upper surface connected to one word line and the lower surface connected to one bit line in a memresistor cell. The memresistor cell within the array can be accessed by a connection to unique word lines and bit lines intersecting at cell locations in the array.

As another example, FIG. 4 provides a schematic of a memresistor array 600 that has multiple diode-containing memresistor cells 610 within areas 620. In this embodiment, one of the diode terminals is connected to a bit line, while the other memresistor cell terminal is connected to the word line.

As a further example, FIG. 5 provides a schematic of a portion of a memresistor array 700 that contains a memresistor cell 705 that contains a three terminal n-channel FET 720 with the gate and drain terminals connected together as one terminal. When either no voltage or a negative voltage is applied to the FET 720 source terminal, the transistor is in the open condition. When a positive voltage is applied to the FET 720 source terminal relative to the word line, the transistor is closed and current passes between the source and drain.

As also shown in FIG. 5, the resistive memory material 710 is connected to FET 720 at one terminal and the word line at its remaining terminal. The application of positive voltage to the bit line forms a closed condition of the switch. If the resistance value of the resistive memory material is low, relatively high current flows through FET 720. If the resistance value is programmed to high resistance, very low current flows through the transistor.

For embodiments comprising unipolar resistive memory materials, the resistive memory material 710 can be programmed to a high-resistance state by applying a voltage of >5V across the bit and word lines. Resistive memory material 710 can also be programmed to a low-resistance state by applying a voltage in the range from 3 to 5V. The state of the device is determined by applying a bias of 1V or less and measuring the current. The FET 720 acts as a diode that blocks current flow from the word line to the bit line and provides isolation between adjacent elements within an array.

Applicants note that the schematics in FIGS. 3-5 contain specific references to electrical switches (e.g., diode in FIG. 4 and n-channel FET in FIG. 5). However, various other electrical switches may be used in variations of the aforementioned embodiments that fall within the scope of the present invention. As discussed previously, such electrical switches can include any types of diodes and transistors previously described.

Methods of Making Memresistor Cells and Arrays

Various methods may be used to make memresistor cells and memresistor arrays. Such methods generally include: (1) forming or embedding an electrical switch onto a substrate; (2) depositing one or more insulating layers on top of the substrate; and (3) depositing a resistive memory material on top of the one or more insulating or conducting layers. In various embodiments, such methods may also include associating two or more conductive elements with the electrical switch.

Various methods may be used to deposit an insulating layer or a resistive memory material. Such methods include, without limitation, chemical vapor deposition (CVD), low-pressure chemical vapor deposition (LPCVD), plasma-enhanced chemical vapor deposition (PECVD), atomic layer deposition (ALD), thermal oxidation, electron-beam evaporation, physical sputter deposition, reactive sputter deposition, and spin coating followed by curing. In some embodiments, the methods may also include a thermal anneal process. In some embodiments, the aforementioned methods may occur under various temperatures and ambient conditions. An exemplary temperature range includes, without limitation, from about 200° C. to about 1200° C. Exemplary sets of thermal anneal ambients include, without limitation, oxygen, nitrogen, argon, helium, hydrogen, deuterium, water vapor, and combinations thereof. In some embodiments, a formed resistive memory material may also be etched by various mechanisms.

For instance, in various embodiments where the resistive memory material is substantially SiOₓ, SiOₓ may be deposited using CVD, LPCVD, PECVD, thermal oxidation of Si, electron-beam evaporation of SiO₂, physical sputter deposition from SiO₂, reactive sputter deposition from Si target in O₂, and spin-coating followed by curing.

Likewise, a method of forming an MEA-containing resistive memory material is to selectively include Si, O, H, C and N in the PECVD process or post deposition processes to incorporate these components into a resistive memory material component (e.g., SiOₓN_{y}, SiOₓC_{y}, SiOₓH_{y}). In some embodiments, the resistive memory material containing MEA may be deposited using PECVD from gaseous growth precursors (such as Si, O, N, H, and combinations thereof) to result in the formation of the resistive memory material components.

In some embodiments, the resistive memory material is first deposited as a SiOₓ layer followed by a thermal anneal process at an ambient temperature range from about 200° C. to about 1200° C. under H₂ flow. The formed SiOₓ layer may then be etched by a reactive ion etch (RIE) plasma with at least one RIE feed gas containing H so that H is incorporated into the etched surface to form SiOₓH_{y}. In some embodiments, the SiOₓ layer may be exposed to a hydrogen fluoride (HF)-containing etchant solution so that H is incorporated into the etched surface to form the compound SiOₓH_{y}, where the x ratio of O to Si is greater than or equal to 1 or less than or equal to 2. In some embodiments, the programmable resistive material comprises SiOₓ that receives a first treatment comprised of etching the SiOₓ layer to form a surface connecting the two conductive elements.

The etched surface may further receive a second treatment comprising a thermal anneal with temperature in the range from 200° C. to 1200° C. in an ambient containing H₂ or H₂O to incorporate H and form compound SiOₓH_{y} at the surface. Depending on anneal time and temperature, in the near-surface regions, the x ratio of Oₓ to Si may be greater than or equal to 1 or less than or equal to 2. In addition, the depth of H incorporation into the SiOₓ material may increase for higher temperatures and longer anneal times. Depending on the deposition method and process conditions, H content in as-deposited SiO₂ films can range from less than 1 atomic percent in dry thermal oxidation of Si to more than 20 atomic percent in films deposited using PECVD. Exposure to an additional thermal anneal containing H, either before or after etching the vertical edge, will allow a consistent H content to be achieved prior to device conditioning, which is described below. Furthermore, the defects associated with the introduction of H into the SiOₓ material may lower the voltage required to condition the device. In general, the H-containing ambient can have a balance of inert gases including N₂ and noble gases such as Ar and He. Other anneal ambients including deuterium (D₂), N₂ and inert noble gases, or combinations thereof, may also be used.

Thermal treatment at reduced pressure (˜140 mTorr) or using purely inert ambients have also been shown to lower the voltage required for electroformation. Defects formed in SiO₂ by thermal stressing in ambients containing only inert gases are expected to form Si-rich SiOₓ with high levels of oxygen vacancy defects that readily absorb moisture when exposed to air or any other environment containing H₂O. As a result, these inert anneal ambients may also be used to promote formation of SiOₓH_{y} compounds in the near-surface region.

In other embodiments, an MEA-containing resistive memory material may be deposited using a single deposition step, with component A being incorporated throughout the deposited layer, and with a layer thickness ranging from a few nanometers to a few micrometers. In other embodiments, a first active layer of composition ME is deposited, with thickness ranging from a few nanometers to a few micrometers. Next, component A is added to form compound MEA. Alternatively, the first layer of composition ME receives an etching treatment to form a surface, wherein component A is incorporated into the etched surface to form compound MEA during the etch treatment.

Conditioning Memresistor Cells

Various methods may be used to condition memresistor cells. In some embodiments, the conditioning may occur by electroforming. Electroforming generally refers to a conditioning process that involves applying a voltage pulse from a low voltage to the conditioning voltage and then to the low voltage. In some embodiments, the conditioning voltage is less than 600 mV per nanometer of the thickness of the resistive memory material. In some embodiments, the voltage may be applied through the first and second conductive elements. In some embodiments, the conductive state is formed on the portion of the pulse from the conditioning voltage to the low voltage.

In some embodiments, the resistive material has at least two resistive states after electroforming: a high resistive state and a low resistive state. In some embodiments, the low resistance “ON” state is programmed by applying 3 to 5 volts across the first and second conductive elements. In some embodiments, the high resistance “OFF” state is set by applying greater than 6 volts and less than 20 volts between the first and second conductive elements.

In some embodiments, the memresistor cells may be conditioned without electroforming. In some embodiments, a low resistance ON state is programmed by applying 3 to 5 volts across the first and second conductive elements. The high resistance OFF state is set by applying greater than 6 volts and less than 20 volts between the first and second conductive elements. In such embodiments, the voltage to read the resistance state is 1 volt or less. In various embodiments, the conditioning voltage is greater than 10 volts and less than 30 volts. In some embodiments, the ON state current is between 10⁶ and 10⁴ times that of the OFF state current.

Applications

The memresistor cells and arrays of the present invention can have numerous applications. In some embodiments, memresistor cells and arrays can be used as addressable two-terminal nonvolatile memory arrays. Compared to conventional flash memory using three-terminal transistors as basic building elements, the memresistor cells and arrays of the present invention adopt a two-terminal configuration and therefore simplify the architecture. This in turn can facilitate the possibility of 3-D memory.

Furthermore, due to a non-charge based mechanism of operation and strong resilience to high-dose X-Ray exposure, the memresistor cells and arrays of the present invention can also be used within the context of nonconventional electronic devices that operate at harsh environments, such as outer space.

Moreover, the components used in the memresistor cells and arrays of the present invention are prevalent and standard. Therefore, the memresistor cells and arrays of the present invention can be fully compatible with the current semiconductor fabrication techniques.

### EXAMPLES

### Example 1

### Fabrication of Diode-Containing Memresistor Cells

This Example outlines the fabrication of a diode-containing memresistor cell 100. FIG. 1 shows a cross-section drawing of memresistor cell 100 having a diode 405 formed in semiconducting substrate 400. Semiconducting substrate 400 is Si. The first doped area 410 in diode 405 is formed by implantation of a dopant element. The second doped area 420 in diode 405 is formed by implantation of a doping element having the opposite effect of the dopant used in the first doped area. The first doped area 410 is p-type, which is achieved from implantation of elements from the group B and In. The second doped area 420 is n-type, which is achieved by implantation of elements from the group P, As, Sb. The substrate can be semiconducting materials other than Si, such as GaAs. In addition, the dopants for p-type and n-type regions will change to those appropriate for the semiconductors used.

First insulating layer 430 is deposited on the substrate. This results in the electrical isolation of diode 405 and the active element parts of substrate 400. The insulating layer 430 is silicon dioxide, which is deposited using silane or tetraethyl orthosilicate (TEOS) based chemistries in a plasma enhanced chemical vapor deposition process.

After deposition of the insulating layer 430, a photoresist is spun on the surface and patterned to have openings over regions of the p-type areas. Plasma etching using fluorine containing gases such as SF₆ or HF acid wet chemical etching is done to remove the SiO₂ from the photoresist openings. After patterning openings in the SiO₂ layer, the photoresist is removed.

The first conductive element 440 is polysilicon deposited on the surface. The photoresist is spun on the patterned surface to provide traces connecting to the first p-type doping area through the openings in the first insulating layer 430. The polysilicon is patterned by etching the areas not covered by photoresist using SF₆ plasma processes. After etching is complete, the photoresist is removed to leave the patterned polysilicon traces of the first conductive layer 440.

The second insulating layer 450 of SiO₂ is deposited on the surface and is chemically and mechanically polished to make insulating layer 450 planar such that its upper surface is substantially parallel to substrate 400. The second insulating layer also has holes patterned through it and the first insulating layer using similar photoresist and etch processes used to pattern the first insulation layer. Second conductive element 460 (i.e., a plug) is formed by depositing a second conductive layer of polysilicon on the patterned surface of the second insulation layer 450 and in the openings to the n-type doping area 420 in the opening etched through the second and first insulating layers. The second conductive layer polysilicon is then removed from the surface of the second insulation layer 450 by chemical mechanical planarization but remains in the openings as a plug 460.

On the surface of the second insulating layer containing the polysilicon plugs 460, the resistive memory material layer 470 is deposited using a silane or TEOS PECVD process. The thickness of the resistive memory material is between 10 nm to about 1000 nm. On the surface of the resistive memory material forming the upper surface of the substrate, a third layer of polysilicon is deposited and patterned using the process described for patterning the previous polysilicon layers to provide trace 480 overlaying the plug 460.

The formed memresistor cell 100 described includes a diode 405 formed in substrate 400 by n-type and p-type areas 410 and 420 in contact, a first layer polysilicon trace bit line 440 connected to one terminal of the diode, a polysilicon plug 460 connecting from the other terminal of the diode to the lower surface of the resistive memory material layer 470, and a polysilicon trace 480 laying over the polysilicon plug in contact with the upper surface of the resistive memory material.

A positive voltage on the bit line will result in current flowing through the diode to the memresistor material. Depending on the programmed resistance value, the resistive material will pass a current to the word line. Sense circuits not included in FIG. 1 may be used to measure the current and assign a high or low logic state value.

### Example 2

### Fabrication of FET-Containing Memresistor Cells

This Example outlines the fabrication of an FET-containing memresistor cell 200. FIG. 2 is a cross section drawing of memresistor cell 200 having an n-channel FET 505 with multiple doped areas formed in semiconducting substrate 500. Substrate 500 is Si, and the first doped area 510 is formed by implantation of a dopant element. The second doped area 520 is formed by implantation of a doping element having the opposite effect of the dopant used in the first doped area. The first doped area 510 is p-type, which is achieved by implantation of B and In. The second doped area is n-type, which is achieved by implantation of P, As, and Sb. The dopants for p-type and n-type regions may change for different semiconductor used.

FET gate 515 consists of a polysilicon trace overlaying an oxide layer. The oxide layer is not shown separate from the polysilicon feature in the drawing. The gate structure is over a channel region between the 520 doped areas. A positive voltage on the gate causes an n-type channel to form, thereby allowing current to flow between the 520 doped areas.

The first insulating layer 530 is deposited on the substrate, thereby electrically isolating the FET and the active element parts of the substrate. The insulating material is silicon dioxide deposited using silane or TEOS based chemistries in a plasma enhanced chemical vapor deposition PECVD process. After deposition of the SiO₂ layer, photoresist is spun on the surface and patterned to have openings over regions of the p-type area to the left of the gate and the gate 515. Plasma etching using fluorine containing gases such as SF₆ or HF acid wet chemical etching is done to remove the SiO₂ from the photoresist openings.

The first conductive layer 540 is poly silicon deposited on the surface. A photoresist is then spun and patterned on the surface to provide traces connecting to the p-type doping area to the left of the gate and the gate through the openings in the first insulating layer. The polysilicon is patterned by etching the areas not covered by photoresist using SF₆ plasma processes. After etching is complete the photoresist is removed leaving the patterned polysilicon traces of the first conductive layer. The second insulating layer 550 of SiO₂ is deposited using PECVD silane or TEOS chemistries on the surface of the substrate.

Insulating layer 550 is chemically and mechanically polished to make it substantially planar to the upper surface of the substrate. The second insulating layer has holes patterned through it and the first insulating layer using the photoresist and etch processes used to pattern the first insulation layer. The plug 560 is formed by depositing a second conductive layer of polysilicon on the patterned surface of the second insulation layer 550 and in the openings to the p-type doping area 520 to the right of the gate. The second conductive layer polysilicon is removed from the surface of the second insulation layer 550 by chemical mechanical planarization but remains in the openings as a plug 560.

On the surface of the second insulating layer containing the polysilicon plugs 560, the resistive memory material layer 570 is deposited to a thickness of about 10 nm to about 1000 nm. This is accomplished by utilizing a silane or TEOS PECVD process. On the surface of resistive memory material, a third layer of polysilicon is deposited and patterned using the process described for patterning the previous polysilicon layers to provide traces 580 overlaying the plugs 560. The trace 580 over the resistive memory material and over the polysilicon plug forms the programmable resistor.

In some embodiments, it is desired to remove the resistive memory material from areas not covered by the traces 580 of the third conductive layer. This is done by selective removal of the memory resistor material in fluorine containing plasma etches with or without photoresist patterns to protect the polysilicon traces. Further, it may be useful to undercut the resistive memory material resulting in feature 595. The feature 595 becomes a cavity when the third insulating layer 590 is deposited on the surface of the substrate. The memresistor cell described includes a transistor 505 formed in substrate 500, a first layer polysilicon trace bit line 540 connected to one terminal of the diode, a polysilicon plug 560 connecting from the other terminal of the diode to the lower surface of the resistive material layer, and a polysilicon trace 580 laying over the polysilicon plug in contact with the upper surface of the resistive memory material.

A positive voltage on the bit line will result in current flowing through the FET to the resistive memory material. Depending on the programmed resistance value of the resistive material, the voltage will pass a current to the word line. Sense circuits not included in FIG. 2 are used to measure the current and assign a high or low logic state value.

### Example 3

### Conditioning of Memresistor Cells

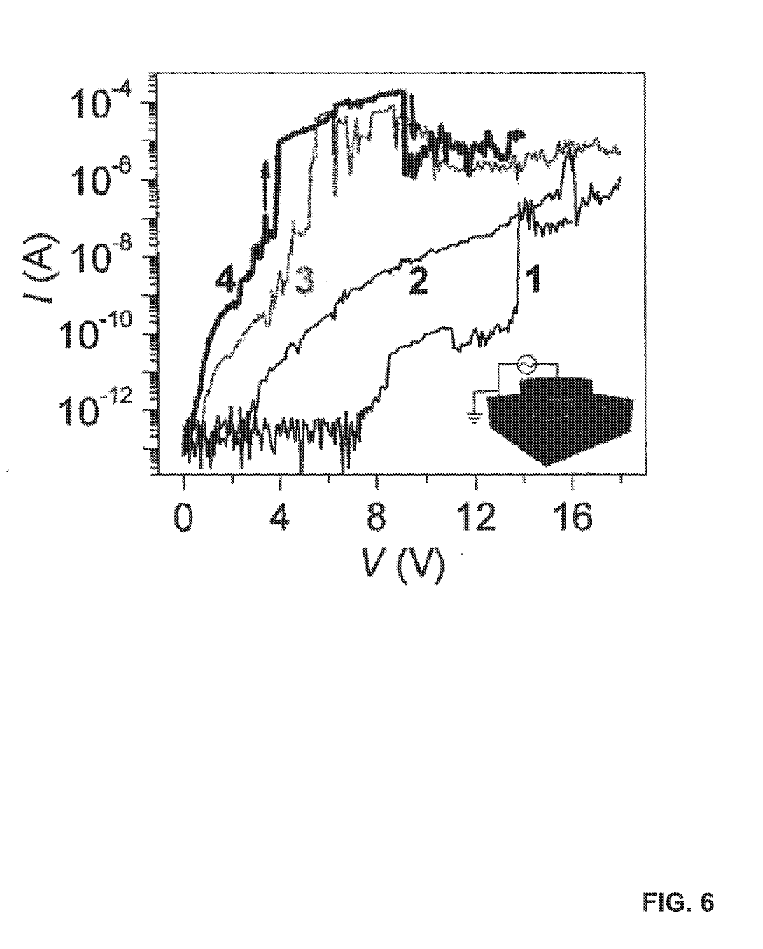

This Example illustrates methods to condition memresistor cells. Conditioning, which is also known as electroforming the resistive material, is accomplished by applying a series of voltage pulses across the bit and word line conductive traces. See FIG. 6. The conditioning voltage pulse has two portions comprised of a ramp of voltage from 0 to a maximum voltage and from the maximum voltage back to 0 volts, where the voltage ramp rates of the two portions of the conditioning voltage pulse can be different. The maximum voltage is determined by resistive material thickness, deposition process settings and thermal history, and typically ranges from 10 to 30 volts. After an initial voltage sweep where approximately 1 micro-ampere of current is measured, subsequent voltage sweeps may be done to less than the maximum voltage. After several voltage sweeps, the resistive memory material takes on attributes of a programmable conductor.

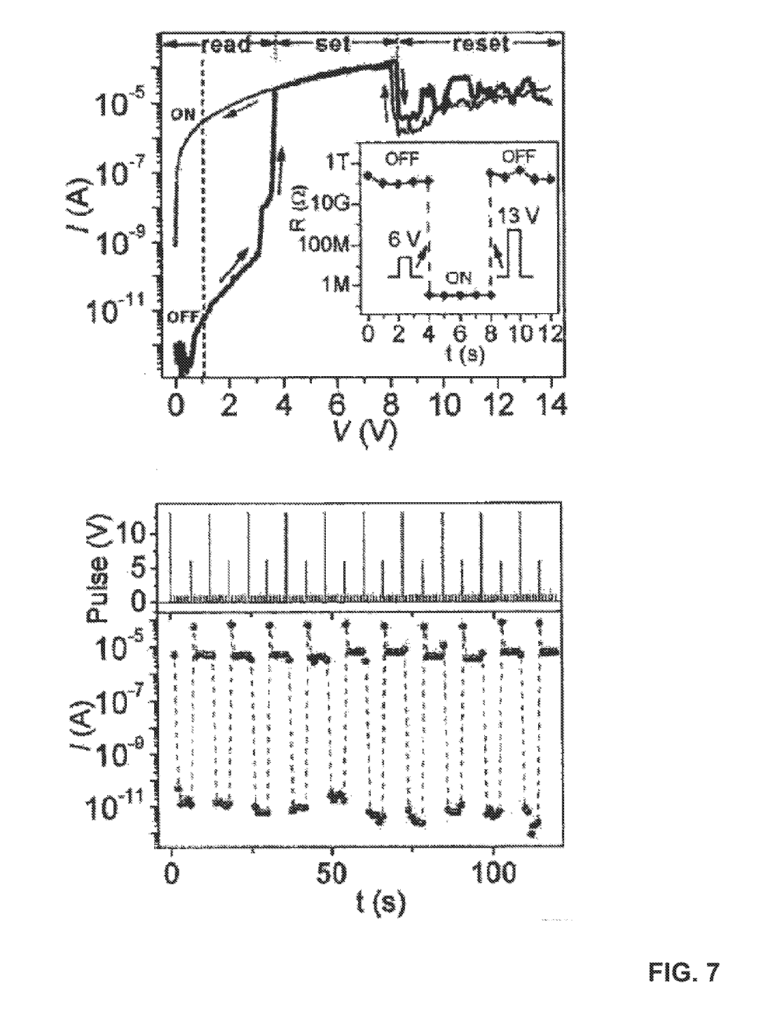

When the programmable material of the memresistor is electroformed, the high resistance OFF state is selected by applying an erase voltage of 6-14 volts between the appropriate word and bit line. The memresistor is programmed to a lower resistance ON state by applying 3-5 volts between the appropriate word lines and bit lines. The read voltage between the word line and bit line to measure the resistance of the memresistor cell is typically 1-2 volts, but can be less than 1 volt. The OFF state has a current in the range of ˜10⁻⁷ amperes or lower and the ON state current is in the range of 10⁻⁶ to 10⁻³ amperes. See FIG. 7. The pulse duration for programming the memresistor's ON and OFF states can be set to between 10 nanoseconds and 10 milliseconds. The ON and OFF states are nonvolatile and are not changed by exposure to x-ray radiation of 2 Mrad dose, temperatures of 450° C. for 30 minutes, or air for extended time periods (such as 3 months or even years).

In various embodiments, the programmable resistive material of components ME comprises SiOₓ that receives a first treatment comprised of etching the SiOₓ layer to form a surface connecting the two conductive elements. The etched surface may further receive a second treatment comprising a thermal anneal with temperature in the range from 200° C. to 1200° C. in an ambient containing H₂ or H₂O to incorporate H and form compound SiOₓH_{y} at the surface. Depending on anneal time and temperature, in the near-surface regions, the ratio of Oₓ to Si may be greater than or equal to 1 and less than or equal to 2. The depth of H incorporation into the SiOₓ material will increase for higher temperature and longer time anneals. The defects associated with the introduction of H into the SiOₓ material may lower the voltage required to electroform the device. The H-containing ambient can have a balance of inert gases including N₂ and noble gases such as Ar and He. Other anneal ambients including deuterium (D₂), N₂ and inert noble gases, or combinations thereof, may be used.

Thermal treatment at reduced pressure (˜140 mTorr) or using purely inert ambients have also been shown to lower the voltage required for electroformation. Defects formed in SiO₂ by thermal stressing in ambients containing only inert gases are expected to form Si-rich SiOₓ with high levels of oxygen vacancy defects that readily react with moisture when exposed to air or any other environment containing H₂O. As a result, these inert anneal ambients may also be used to form SiOₓH_{y} compounds in the near-surface region.

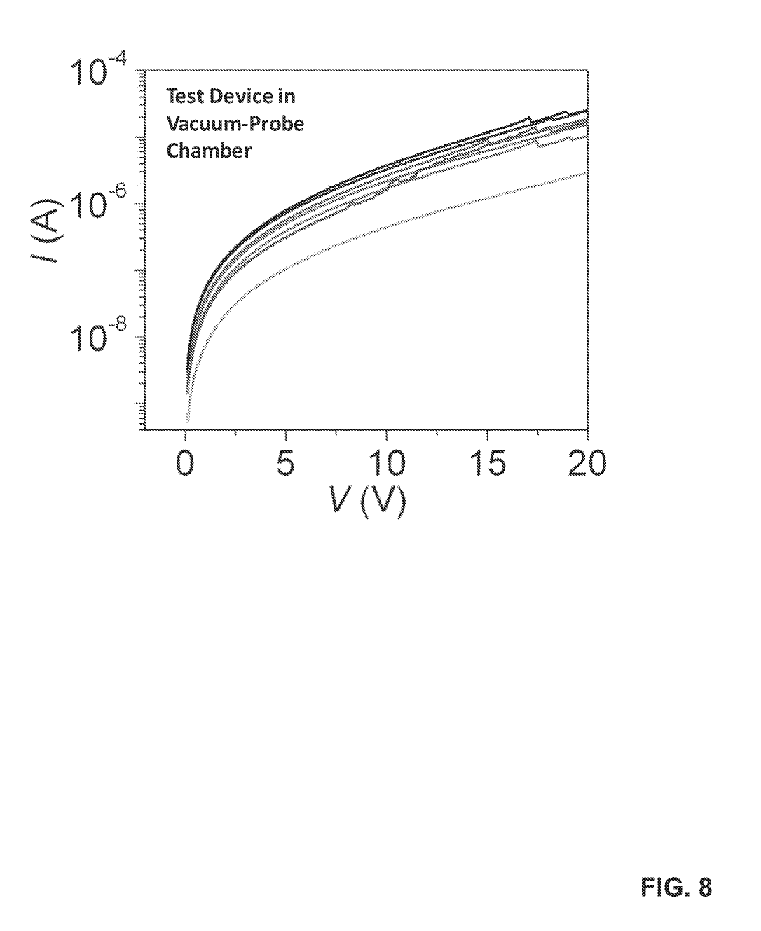

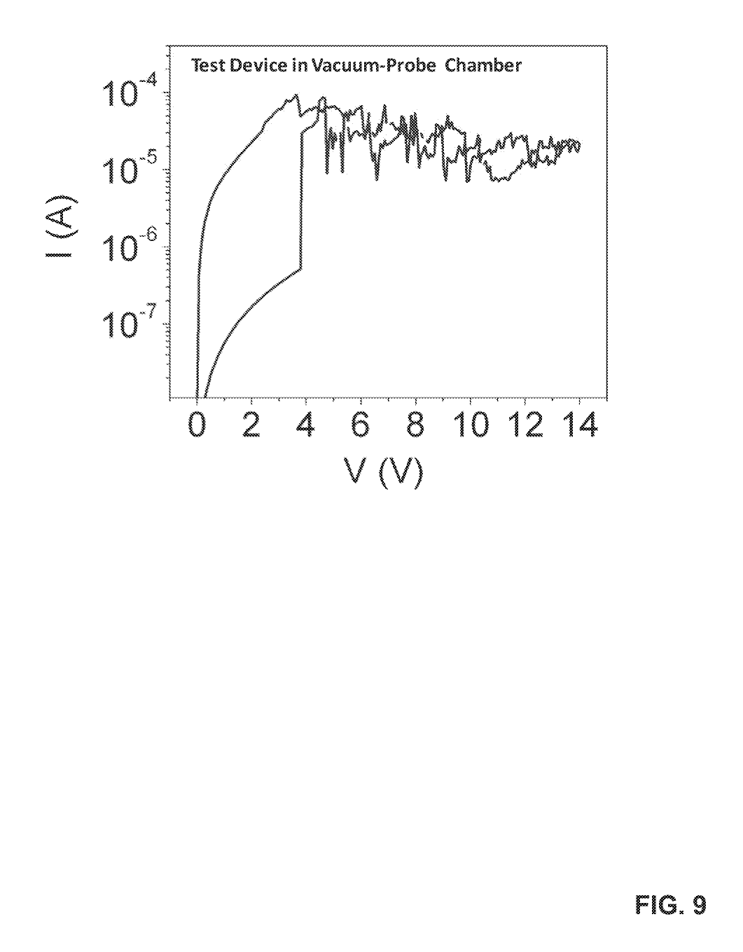

FIG. 8 shows the initial leakage current, prior to electroforming, of a SiOₓ device deposited using PECVD and receiving a 30-minute, 450° C. anneal using 10% H₂ in N₂ at atmospheric pressure (forming gas anneal). Numerous devices were electroformed and tested in a vacuum probe chamber at ˜10⁻⁵ Torr. The switching performance of one device is shown in FIG. 9. The data indicate a switching ON/OFF ratio of ˜100 with relatively high OFF-state current, which is attributed to the forming gas anneal enhancing the leakage current from top electrode to bottom electrode along the SiO₂ vertical edge, even prior to electroformation (as shown in FIG. 8).

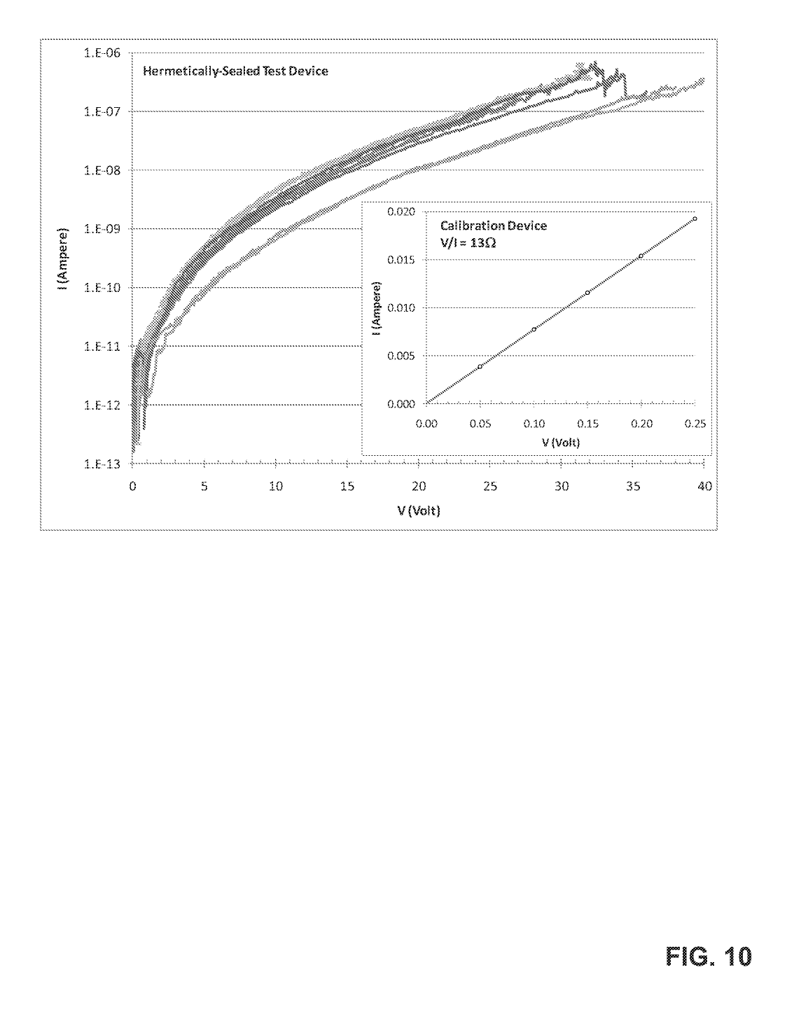

FIG. 10 shows the initial leakage current of a SiOₓ device from the same wafer as the device shown in FIG. 8. However, the device in FIG. 10 was hermetically sealed in a ceramic package. The hermetic sealing process includes a high-temperature (>250° C.) bake-out step to remove any moisture contamination from inside the package and from the SiOₓ device test chip, followed immediately by hermetic sealing of the package under vacuum at ˜1 mTorr pressure and temperature greater than the melting point of the AuSn sealing material. The leakage current plot shown in FIG. 10 indicates that the high leakage current observed in FIG. 8 during vacuum-probe is no longer present inside the hermetically-sealed package. The inset of FIG. 10 shows the current-voltage response of a calibration device that was purposely short-circuited, indicating a series resistance of 13Ω and demonstrating that the wire-bond connections to the test chip inside the package are intact. Repeated attempts to electroform hermetically sealed devices were unsuccessful, even when applying voltages of up to 40V as shown in FIG. 10, demonstrating that trace moisture may be required to electroform the SiOₓ device as noted in other types of memristive devices using SiO₂ materials.

Without further elaboration, it is believed that one skilled in the art can, using the description herein, utilize the present invention to its fullest extent. The embodiments described herein are to be construed as illustrative and not as constraining the remainder of the disclosure in any way whatsoever. While the preferred embodiments have been shown and described, many variations and modifications thereof can be made by one skilled in the art without departing from the spirit and teachings of the invention. Accordingly, the scope of protection is not limited by the description set out above, but is only limited by the claims, including all equivalents of the subject matter of the claims. The disclosures of all patents, patent applications and publications cited herein are hereby incorporated herein by reference, to the extent that they provide procedural or other details consistent with and supplementary to those set forth herein.

What is claimed is:

1. A memresistor cell comprising:
a substrate;
an electrical switch associated with the substrate;
an insulating layer; and
a resistive memory material,
wherein the resistive memory material is selected from the group consisting of SiOₓ, SiOₓH, SiOₓN_{y}, SiOₓN_{y}H, SiOₓC_{z}, SiOₓC_{z}H, and combinations thereof, wherein each of x, y and z are equal or greater than 1 or equal or less than 2.

2. The memresistor cell of claim 1, wherein the memresistor cell has two terminals.

3. The memresistor cell of claim 1, wherein the substrate is selected from the group consisting of silicon, silicon dioxide, aluminum oxide, sapphire, germanium, gallium arsenide (GaAs), alloys of silicon and germanium, indium phosphide (InP), and combinations thereof.

4. The memresistor cell of claim 1, wherein the electrical switch is associated with two or more conductive elements.

5. The memresistor cell of claim 4, wherein the conductive elements associated with the electrical switch are selected from the group consisting of polysilicon, n-doped polysilicon, p-doped polysilicon, doped single-crystal silicon, metal silicides, tungsten, titanium, titanium nitride, titanium silicide, titanium tungsten, cobalt silicide, nickel silicide, tantalum, tantalum nitride, aluminum, gold, copper and combinations thereof.

6. The memresistor cell of claim 1, wherein the electrical switch is a diode.

7. The memresistor cell of claim 6, wherein the diode is selected from the group consisting of n-p diodes, p-n diodes, Schottky diodes, and combinations thereof.

8. The memresistor cell of claim 1, wherein the electrical switch is a transistor.

9. The memresistor of claim 8, wherein the transistor is selected from the group consisting of FETs, n-channel FETs, p-channel FETs, MOS transistors, MOS FETs, and bipolar FETs.

10. The memresistor cell of claim 1, wherein the insulating layer is selected from the group consisting of SiO₂, Si₃N₄, SiCOH, Al₂O₃, polyimide materials and combinations thereof.

11. The memresistor cell of claim 1, further comprising a second insulating layer.

12. The memresistor cell of claim 1, wherein the resistive memory material has a thickness between about 10 nm to about 1000 nm.

13. The memresistor cell of claim 1, wherein the resistive memory material comprises SiO₂.

14. The memresistor cell of claim 1, wherein the resistive memory material comprises hydrogenated SiO₂.

15. The memresistor cell of claim 14, wherein the hydrogenated SiO₂ is exposed to thermal anneal in ambient comprising at least one of H₂, H₂O and D₂.

16. The memresistor cell of claim 1, wherein the resistive memory material is associated with two or more conductive elements.

17. The memresistor cell of claim 1, wherein the resistive memory material further comprises an MEA compound, wherein:
M is selected from the group consisting of Si, C, Ge, In, Sn, Pb, Ti, Zr, Hf, Sr, Ba, Y, La, V, Nb, Ta, Cr, Mo, W, Fe, Ni, Cu, Ag, Zn, Al, and combinations thereof;
E is selected from the group consisting of O, N, P, B, Sb, S, Se, Te, and combinations thereof; and
A is selected from the group consisting of H, Li, Na, K, F, Cl, Br, I and combinations thereof.

18. The memresistor cell of claim 1, wherein the resistive memory material has at least two programmable resistance states.

19. The memresistor cell of claim 1, wherein the insulating layer is above the substrate and the electrical switch, and wherein the resistive memory material is above the insulating layer.

20. A memresistor array comprising:
a plurality of bit lines;
a plurality of word lines orthogonal to the bit lines; and
a plurality of memresistor cells positioned between the word lines and the bit lines, wherein the memory cells comprise:
a substrate;
an electrical switch associated with the substrate;
an insulating layer; and
a resistive memory material, wherein the resistive memory material is selected from the group consisting of SiOₓ, SiOₓH, SiOₓN_{y}, SiOₓN_{y}H, SiOₓC_{z}, SiOₓC_{z}H, and combinations thereof, wherein each of x, y and z are equal or greater than 1 or equal or less than 2.

21. The memresistor array of claim 20, wherein the insulating layer is above the substrate and the electrical switch, and wherein the resistive memory material is above the insulating layer.

22. The memresistor array of claim 20, wherein the memresistor cells have two terminals.

23. The memresistor array of claim 20, wherein the electrical switch is a diode selected from the group consisting of n-p diodes, p-n diodes, Schottky diodes, and combinations thereof.

24. The memresistor array of claim 20, wherein the electrical switch is a transistor selected from the group consisting of FETs, n-channel FETs, p-channel FETs, MOS transistors, MOS FETs, and bipolar FETs.

25. A method of forming a memresistor cell, wherein the method comprises:
forming or embedding an electrical switch onto a substrate;
depositing one or more insulating layers on top of the substrate; and
depositing a resistive memory material on top of the one or more insulating layers, wherein the resistive memory material is selected from the group consisting of SiOₓ, SiOₓH, SiOₓN_{y}, SiOₓN_{y}H, SiOₓC_{z}, SiOₓC_{z}H, and combinations thereof, wherein each of x, y and z are equal or greater than 1 or equal or less than 2.

26. The method of claim 25, wherein the electrical switch is a diode selected from the group consisting of n-p diodes, p-n diodes, Schottky diodes, and combinations thereof.

27. The method of claim 25, wherein the electrical switch is a transistor selected from the group consisting of FETs, n-channel FETs, p-channel FETs, MOS transistors, MOS FETs, and bipolar FETs.

28. The method of claim 25, further comprising associating two or more conductive elements with the electrical switch.

29. The method of claim 28, wherein the conductive elements are selected from the group consisting of polysilicon, n-doped polysilicon, p-doped polysilicon, doped single-crystal silicon, metal silicides, tungsten, titanium, titanium nitride, titanium silicide, titanium tungsten, cobalt silicide, nickel silicide, tantalum, tantalum nitride, aluminum, gold, copper and combinations thereof.

30. The method of claim 25, wherein the depositing of one or more insulating layers occurs by plasma enhanced chemical vapor deposition.

31. The method of claim 25, wherein the depositing of the resistive memory material occurs by at least one of chemical vapor deposition, low-pressure chemical vapor deposition, plasma-enhanced chemical vapor deposition, atomic layer deposition, thermal oxidation, electron-beam evaporation, physical sputter deposition, reactive sputter deposition, spin coating followed by curing, thermal annealing, and combinations thereof.
